(19) United States
(12) Patent Application Publication
(10) Pub. No.: US 2025/0149245 A1
(43) Pub. Date: May 8, 2025

(54) DIELECTRIC FILM, CAPACITOR COMPRISING SAME AND MANUFACTURING METHODS THEREFOR

(71) Applicant: JUSUNG ENGINEERING CO., LTD., Gwangju-si, Gyeonggi-do (KR)

(72) Inventors: Hong Min YOON, Gwangju-si, Gyeonggi-do (KR); Yong Chan KWON, Gwangju-si, Gyeonggi-do (KR); Joo Sung KIM, Gwangju-si, Gyeonggi-do (KR); Hye Young KIM, Gwangju-si, Gyeonggi-do (KR); Min Gyu PARK, Gwangju-si, Gyeonggi-do (KR); Chang Kyun PARK, Gwangju-si, Gyeonggi-do (KR); Min Wook BANG, Gwangju-si, Gyeonggi-do (KR); Jae Wuk SO, Gwangju-si, Gyeonggi-do (KR); Hong Soo YOON, Gwangju-si, Gyeonggi-do (KR); Youn Joo JANG, Gwangju-si, Gyeonggi-do (KR); Chul Joo HWANG, Gwangju-si (KR)

(21) Appl. No.: 18/833,873

(22) PCT Filed: Feb. 22, 2023
(86) PCT No.: PCT/KR2023/002521

§ 371 Date: Jul. 26, 2024

(30) Foreign Application Priority Data
Feb. 24, 2022 (KR) 10-2022-0024035
Feb. 21, 2023 (KR) 10-2023-0022916

(51) Int. Cl. H01G 4/12; H01G 4/33

(52) U.S. Cl. CPC H01G 4/1272; H01G 4/33

(57) ABSTRACT

The present inventive concept provides a method of forming a dielectric film comprising a step of supplying a first source gas; a step of supplying a first purge gas; a step of supplying a first reaction gas; and a step of supplying a second purge gas, wherein the step of supplying the first source gas comprises supplying a compound containing at least one metal selected from the group consisting of lanthanum (La), cerium (Ce), strontium (Sr), gadolinium (Gd), hafnium (Hf), and zirconium (Zr) into a vacuum deposition apparatus, and wherein the step of supplying the first reaction gas comprises supplying a compound selected from the group consisting of O₃ and H₂O into the vacuum deposition apparatus.

### TECHNICAL FIELDS

The present inventive concept relates to a dielectric film, and more particularly, to a dielectric film applicable to a capacitor.

### BACKGROUND ART

The capacitor has a structure in which a dielectric film is provided between two electrodes. The characteristics of the capacitor depend greatly on the dielectric characteristics of the dielectric layer.

In general, the dielectric characteristics of a dielectric film used in a capacitor may be evaluated by the thickness and leakage current density of the dielectric film.

As the thickness of the dielectric film decreases, capacitance per unit area increases, and thus it is preferable that the thickness of the dielectric film is formed to be thinner.

In addition, it is desirable to reduce the leakage current density because the power consumption of the capacitor increases as the leakage current density increases.

### DISCLOSURE

### Technical Problem

The present inventive concept is devised to solve the above-described problem, and it is an object of the present inventive concept to provide a dielectric film capable of reducing leakage current density while forming a thin film, a method of forming the dielectric film, a capacitor including the dielectric film, and a method of forming the capacitor.

### Technical Solution

In order to achieve the above object, according to an embodiment of the present inventive concept, a method of forming a dielectric film comprises a step of supplying a first source gas; a step of supplying a first purge gas; a step of supplying a first reaction gas; and a step of supplying a second purge gas, wherein the step of supplying the first source gas comprises supplying a compound containing at least one metal selected from the group consisting of lanthanum (La), cerium (Ce), strontium (Sr), gadolinium (Gd), hafnium (Hf), and zirconium (Zr) into a vacuum deposition apparatus, and wherein the step of supplying the first reaction gas comprises supplying a compound selected from the group consisting of O₃ and H₂O into the vacuum deposition apparatus.

According to another embodiment of the present inventive concept, a method of forming a dielectric film comprises a step of supplying a first source gas; a step of supplying a first purge gas; a step of supplying a second source gas; a step of supplying a second purge gas; a step of supplying a first reaction gas; and a step of supplying a third purge gas, wherein the step of supplying the first source gas comprises supplying a first compound containing a first metal selected from the group consisting of lanthanum (La), cerium (Ce), strontium (Sr), gadolinium (Gd), hafnium (Hf), and zirconium (Zr) into a vacuum deposition apparatus, wherein the step of supplying the second source gas comprises supplying a second compound containing a second metal different from the first metal and selected from the group consisting of lanthanum (La), cerium (Ce), strontium (Sr), gadolinium (Gd), hafnium (Hf), and zirconium (Zr) into the vacuum deposition apparatus, and wherein the step of supplying the first reaction gas comprises supplying a compound selected from the group consisting of O₃ and H₂O into the vacuum deposition apparatus.

According to another embodiment of the present inventive concept, a method of forming a dielectric film comprises a step of supplying a first source gas; a step of supplying a first purge gas; a step of supplying a first reaction gas; a step of supplying a second purge gas;

a step of supplying a second source gas; a step of supplying a third purge gas; a step of supplying a second reaction gas; and a step of supplying a fourth purge gas, wherein the step of supplying the first source gas comprises supplying a compound containing at least one metal selected from the group consisting of lanthanum (La), cerium (Ce), strontium (Sr), gadolinium (Gd), hafnium (Hf), and zirconium (Zr) into a vacuum deposition apparatus, wherein the step of supplying the second source gas comprises supplying a compound containing at least one metal selected from the group consisting of lanthanum (La), cerium (Ce), strontium (Sr), gadolinium (Gd), hafnium (Hf), and zirconium (Zr) into the vacuum deposition apparatus, wherein the second source gas is different from the first source gas, and wherein each of the step of supplying the first reaction gas and the step of supplying the second reaction gas comprises supplying a compound selected from the group consisting of O₃ and H₂O into the vacuum deposition apparatus.

According to an embodiment of the present inventive concept, a method of forming a capacitor having a first electrode, a second electrode, and a dielectric film between the first electrode and the second electrode comprises forming the dielectric film as described above.

According to an embodiment of the present inventive concept, a dielectric film comprises an oxide of a composite metal, wherein the composite metal includes a first metal selected from the group consisting of lanthanum (La), cerium (Ce), strontium (Sr), gadolinium (Gd), hafnium (Hf), and zirconium (Zr), and a second metal selected from the group consisting of lanthanum (La), cerium (Ce), strontium (Sr), gadolinium (Gd), hafnium (Hf), and zirconium (Zr), the second metal being different from the first metal.

According to an embodiment of the present inventive concept, a dielectric film comprises a first dielectric film; and a second dielectric film on the first dielectric film and formed of a different material from the first dielectric film, wherein the first dielectric film comprises an oxide of a first metal, or an oxide of a composite metal comprising a first metal and a second metal, the first metal being different from the second metal, wherein the second dielectric film comprises an oxide of a third metal, or an oxide of a composite metal comprising a third metal and a fourth metal, the third metal being different from the fourth metal, and wherein each of the first metal, the second metal, the third metal and the fourth metal is selected from the group consisting of lanthanum (La), cerium (Ce), strontium (Sr), gadolinium (Gd), hafnium (Hf), and zirconium (Zr).

According to an embodiment of the present inventive concept, a capacitor comprises a first electrode; a second electrode; and a dielectric film between the first electrode and the second electrode, wherein the dielectric film is a dielectric film as described above.

### ADVANTAGEOUS EFFECT

According to the present inventive concept as described above, there are the following effects.

According to one embodiment of the present inventive concept, a dielectric film is formed of an oxide of at least one metal of lanthanum (La), cerium (Ce), strontium (Sr), gadolinium (Gd), hafnium (Hf), or zirconium (Zr) using an atomic layer deposition method. Thus, the dielectric film may be formed to be thin and crystallization of the dielectric film is improved, thereby leakage current density is reduced when the dielectric film is applied to a capacitor.

### DESCRIPTION OF DRAWINGS

FIG. 1 illustrates a method of forming a dielectric film according to an embodiment of the present inventive concept.

FIG. 2 illustrates a method of forming a dielectric film according to another embodiment of the present inventive concept.

FIG. 3 illustrates a method of forming a dielectric film according to another embodiment of the present inventive concept.

FIG. 4 is a schematic cross-sectional view of a capacitor according to an embodiment of the present inventive concept.

FIG. 5 is a schematic cross-sectional view of a capacitor according to another embodiment of the present inventive concept.

FIG. 6 is a schematic exploded perspective view of a vacuum deposition apparatus according to an embodiment of the present inventive concept.

FIG. 7 is a schematic side cross-sectional view of a vacuum deposition apparatus according to an embodiment of the present inventive concept based on line I-I of FIG. 6.

FIG. 8 is a schematic plan view of a support portion in a vacuum deposition apparatus according to an embodiment of the present inventive concept.

FIG. 9 is a schematic side cross-sectional view of a vacuum deposition apparatus according to another embodiment of the present inventive concept based on line I-I of FIG. 6.

### MODE FOR THE INVENTIVE CONCEPT

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Further, the present disclosure is only defined by scopes of claims.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted. When “comprise,” “have,” and “include” described in the present specification are used, another part may be added unless “only” is used. The terms of a singular form may include plural forms unless referred to the contrary.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts may be disposed between the two parts unless a more limiting term, such as “just” or “direct(ly)” is used.

In describing a time relationship, for example, when the temporal order is described as, for example, “after,” “subsequent,” “next,” and “before,” a case that is not continuous may be included unless a more limiting term, such as “just,” “immediate(ly),” or “direct(ly)” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various embodiments of the present disclosure may be partially or overall coupled to or combined with each other, and may be variously inter-operated with each other and driven technically as those skilled in the art may sufficiently understand. The embodiments of the present disclosure may be carried out independently from each other, or may be carried out together in co-dependent relationship.

Hereinafter, embodiments of the present disclosure will be described in detail with reference to the accompanying drawings. In adding reference numerals to elements of each of the drawings, although the same elements are illustrated in other drawings, like reference numerals may refer to like elements.

Hereinafter, a preferable embodiment of the present inventive concept will be described in detail with reference to the accompanying drawings.

FIG. 1 illustrates a method of forming a dielectric film according to an embodiment of the present inventive concept.

The dielectric film in accordance with an embodiment of this inventive concept can be formed through atomic layer deposition (ALD) using vacuum deposition apparatus.

As shown in FIG. 1, the method of forming a dielectric film according to an embodiment of the present inventive concept includes a step of supplying a first source gas, a step of supplying a first purge gas, a step of supplying a first reaction gas, and a step of supplying a second purge gas.

The step of supplying the first source gas may include a step of loading a substrate in the vacuum deposition apparatus and supplying the first source gas into the vacuum deposition apparatus.

The first source gas may include a first compound containing any one first metal selected from the group consisting of lanthanum (La), cerium (Ce), strontium (Sr), gadolinium (Gd), hafnium (Hf), and zirconium (Zr).

Here, the compound containing lanthanum (La) may be selected from the group consisting of La(NPMP)₃ (tris(1-n-propoxy-2-methyl-2-propoxy)lanthanum(III)), La(NPEB)₃ (tris(2-ethyl-1-n-propoxy-2-butoxy)lanthanum(III)), La(OC2H5)3 (lanthanum(III) ethoxide), La(EDMDD)₃ (tris(6-ethyl-2,2-dimethyl-3,5-decanedionato)lanthanum(III)), La(DPM)₃ (tris(dipivaloylmethanate)lanthanum(III)), La(TMHD)₃ (tris(2,2,6,6-tetramethyl-3,5-heptanedionato) lanthanum(III)), La(acac)₃ (lanthanum(III) acethylacetonate), and La(EtCp)₃ (tris(ethylcyclopentadienyl)lanthanum(III)), but is not necessarily limited thereto.

The compound containing cerium (Ce) may be selected from the group consisting of cerium nitrate (Ce(NO₃)₃·6H₂O), cerium acetate (Ce(O₂C₂H₃)₃·xH2O), and cerium chloride (CeCl₃·xH₂O), but is not limited thereto.

The compound containing strontium (Sr) may be selected from the group consisting of Sr(thd)₂THF₂, Sr(NO₃)₂, and Sr(CH₃COO)₂·nH₂O (n is a natural number between 5 and 9), but is not limited thereto.

The compound containing gadolinium (Gd) may be selected from the group consisting of Gd(thd)₃ or Cp(CH₃)₃Gd, but is not necessarily limited to it.

The compound containing hafnium (Hf) may be selected from the group consisting of HfCl₄, Hf(OC₂H₅)₄, Hf(N(C₂H₅)₂)₄, Hf(N(CH₃)₂)₄, and Hf(dimethylamine) 4, but is not limited thereto.

The compound containing zirconium (Zr) may be selected from the group consisting of Zr[NC₂H₅CH₃]₄, Zr[N(CH₃)₂]₄, Zr[OC(CH₃)₂CH₂OCH₃]₄, Zr[OC(CH₃)₃]₄, ZrCl₄, and ZrI₄, but is not limited thereto.

Alternatively, the first source gas may include a first compound containing any one first metal selected from the group consisting of lanthanum (La), cerium (Ce), strontium (Sr), gadolinium (Gd), hafnium (Hf), and zirconium (Zr), and a second compound different from the first compound and including another second metal selected from the group consisting of lanthanum (La), cerium (Ce), strontium (Sr), gadolinium (Gd), hafnium (Hf), and zirconium (Zr).

For example, the first compound may contain any one first metal selected from the group consisting of lanthanum (La), cerium (Ce), strontium (Sr), and gadolinium (Gd), and the second compound may contain another second metal selected from the group consisting of hafnium (Hf) and zirconium (Zr).

Alternatively, the first compound may contain any one first metal selected from the group consisting of cerium (Ce) and gadolinium (Gd), and the second compound may contain another second metal selected from the group consisting of lanthanum (La), strontium (Sr), hafnium (Hf), and zirconium (Zr).

The step of supplying the first purge gas may be performed simultaneously with stopping the supply of the first source gas. The first purge gas may use various purge gases known in the art, for example, an inert gas such as argon (Ar), and the first source gas remaining in the vacuum deposition apparatus is purged by the supply of the first purge gas.

The step of supplying the first reaction gas may be performed simultaneously with stopping the supply of the first purge gas.

The first reaction gas may be selected from the group consisting of O₃ and H₂O. The first reaction gas may be formed of O₃, H₂O, or a mixture of O₃ and H₂O.

The step of supplying the second purge gas may be performed simultaneously with stopping the supply of the first reaction gas. The second purge gas may use various purge gases known in the art, and the first reaction gas remaining in the vacuum deposition apparatus is purged by the supply of the second purge gas.

According to an embodiment of this inventive concept, one cycle is completed by a combination of the first source gas supply step, the first purge gas supply step, the first reaction gas supply step, and the second purge gas supply step, and the dielectric film may be formed by repeating the cycle.

When the first source gas is formed of a first compound containing any one first metal selected from the group consisting of lanthanum (La), cerium (Ce), strontium (Sr), gadolinium (Gd), hafnium (Hf), and zirconium (Zr), the obtained dielectric film may be formed of an oxide of the selected first metal, e.g., an oxide of a first metal of any one of lanthanum (La), cerium (Ce), strontium (Sr), gadolinium (Gd), hafnium (Hf), and zirconium (Zr).

When the first source gas include a first compound containing any one first metal selected from the group consisting of lanthanum (La), cerium (Ce), strontium (Sr), gadolinium (Gd), hafnium (Hf), and zirconium (Zr), and a second compound different from the first compound and including another second metal selected from the group consisting of lanthanum (La), cerium (Ce), strontium (Sr), gadolinium (Gd), hafnium (Hf), and zirconium (Zr), the obtained dielectric film may be formed of an oxide of a composite metal including any one first metal contained in the first compound and another second metal contained in the second compound.

The dielectric film manufactured according to an embodiment of the present inventive concept has improved crystallization of a thin film, and when applied to a capacitor, a leakage current problem may be prevented.

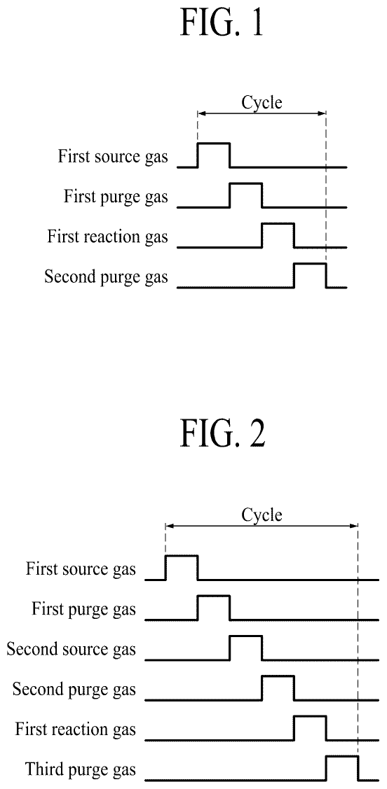

FIG. 2 illustrates a method of forming a dielectric film according to another embodiment of the present inventive concept.

As shown in FIG. 2, a method of forming a dielectric film according to another embodiment of this inventive concept includes a step of supplying a first source gas, a step of supplying a first purge gas, a step of supplying a second source gas, a step of supplying a second purge gas, a step of supplying a first reaction gas, and a step of supplying a third purge gas.

The step of supplying the first source gas may include a step of loading a substrate in a vacuum deposition apparatus and supplying the first source gas into the vacuum deposition apparatus.

The first source gas may include a first compound containing any one first metal selected from the group consisting of lanthanum (La), cerium (Ce), strontium (Sr), gadolinium (Gd), hafnium (Hf), and zirconium (Zr).

The step of supplying the first purge gas may be performed simultaneously with stopping the supply of the first source gas. The first purge gas may use various purge gases known in the art, and the first source gas remaining in the vacuum deposition apparatus is purged by the supply of the first purge gas.

The step of supplying the second source gas may be performed simultaneously with stopping the supply of the first purge gas.

The second source gas is different from the first compound and may include a second compound containing another second metal selected from the group consisting of lanthanum (La), cerium (Ce), strontium (Sr), gadolinium (Gd), hafnium (Hf), and zirconium (Zr).

The first compound may include any one first metal selected from the group consisting of lanthanum (La), cerium (Ce), strontium (Sr), and gadolinium (Gd), and the second compound may include another second metal selected from the group consisting of hafnium (Hf) and zirconium (Zr).

Alternatively, the first compound may contain any one first metal selected from the group consisting of cerium (Ce) and gadolinium (Gd), and the second compound may contain another second metal selected from the group consisting of lanthanum (La), strontium (Sr), hafnium (Hf), and zirconium (Zr).

The step of supplying the second purge gas may be performed simultaneously with stopping the supply of the second source gas. The second purge gas may use various purge gases known in the art, and the second source gas remaining in the vacuum deposition apparatus is purged by the supply of the second purge gas.

The step of supplying the first reaction gas may be performed simultaneously with stopping the supply of the second purge gas.

The first reaction gas may be formed of O₃, H₂O, or a mixture of O₃ and H₂O.

The step of supplying the third purge gas may be performed simultaneously with stopping the supply of the first reaction gas. The third purge gas may use various purge gases known in the art, and the first reaction gas remaining in the vacuum deposition apparatus is purged by the supply of the third purge gas.

According to another embodiment of this inventive concept, one cycle is completed by a combination of the first source gas supply step, the first purge gas supply step, the second source gas supply step, the second purge gas supply step, the first reaction gas supply step, and the third purge gas supply step, and the dielectric film may be formed by repeating the cycle.

The dielectric film formed according to another embodiment of the present inventive concept may be formed of an oxide of a composite metal including any one first metal contained in the first compound and the other second metal contained in the second compound.

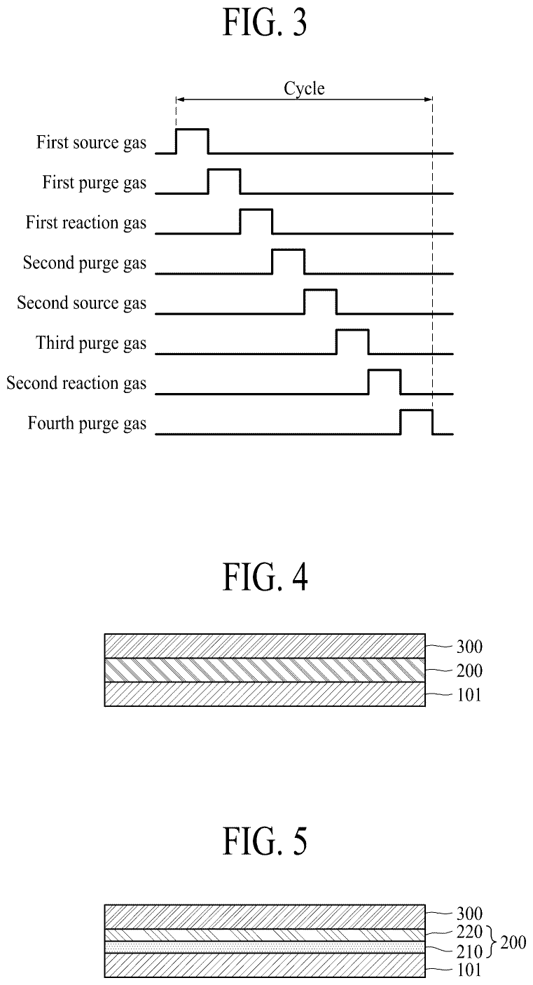

FIG. 3 illustrates a method of forming a dielectric film according to another embodiment of the present inventive concept.

As shown in FIG. 3, a method of forming a dielectric film according to another embodiment of this inventive concept includes a step of supplying a first source gas, a step of supplying a first purge gas, a step of supplying a first reaction gas, a step of supplying a second purge gas, a step of supplying a second source gas, a step of supplying a third purge gas, a step of supplying a second reaction gas, and a step of supplying a fourth purge gas.

The step of supplying the first source gas may include a step of loading a substrate in a vacuum deposition apparatus and supplying the first source gas into the vacuum deposition apparatus.

The first source gas may include a first compound containing any one first metal selected from the group consisting of lanthanum (La), cerium (Ce), strontium (Sr), gadolinium (Gd), hafnium (Hf), and zirconium (Zr).

Alternatively, the first source gas may include a first compound containing any one first metal selected from the group consisting of lanthanum (La), cerium (Ce), strontium (Sr), gadolinium (Gd), hafnium (Hf), and zirconium (Zr), and a second compound different from the first compound and including another second metal selected from the group consisting of lanthanum (La), cerium (Ce), strontium (Sr), gadolinium (Gd), hafnium (Hf), and zirconium (Zr).

The first compound may contain any one first metal selected from the group consisting of lanthanum (La), cerium (Ce), strontium (Sr), and gadolinium (Gd), and the second compound may contain another second metal selected from the group consisting of hafnium (Hf) and zirconium (Zr).

Alternatively, the first compound may contain any one first metal selected from the group consisting of cerium (Ce) and gadolinium (Gd), and the second compound may contain another second metal selected from the group consisting of lanthanum (La), strontium (Sr), hafnium (Hf), and zirconium (Zr).

The step of supplying the first purge gas may be performed simultaneously with stopping the supply of the first source gas. The first purge gas may use various purge gases known in the art, and the first source gas remaining in the vacuum deposition apparatus is purged by the supply of the first purge gas.

The step of supplying the first reaction gas may be performed simultaneously with stopping the supply of the first purge gas.

The first reaction gas may be formed of O₃, H₂O, or a mixture of O₃ and H₂O.

The step of supplying the second purge gas may be performed simultaneously with stopping the supply of the first reaction gas. The second purge gas may use various purge gases known in the art, and the first reaction gas remaining in the vacuum deposition apparatus is purged by the supply of the second purge gas.

The step of supplying the second source gas may be performed simultaneously with stopping the supply of the second purge gas.

The second source gas is made of a compound different from the first source gas.

The second source gas may include a third compound containing any one third metal selected from the group consisting of lanthanum (La), cerium (Ce), strontium (Sr), gadolinium (Gd), hafnium (Hf), and zirconium (Zr).

The third compound is formed of a material different from the first compound. The third compound can be formed of a material different from the first compound and the second compound.

Alternatively, the second source gas may include a third compound containing any one third metal selected from the group consisting of lanthanum (La), cerium (Ce), strontium (Sr), gadolinium (Gd), hafnium (Hf), and zirconium (Zr), and a fourth compound different from the third compound and including another fourth metal selected from the group consisting of lanthanum (La), cerium (Ce), strontium (Sr), gadolinium (Gd), hafnium (Hf), and zirconium (Zr).

The third compound is formed of a material different from the first compound. The third compound can be formed of a material different from the first compound and the second compound.

The fourth compound is formed of a material different from the first compound. The fourth compound can be formed of a material different from the first compound and the second compound.

The third compound may include any one third metal selected from the group consisting of lanthanum (La), cerium (Ce), strontium (Sr), and gadolinium (Gd), and the fourth compound may include another fourth metal selected from the group consisting of hafnium (Hf) and zirconium (Zr).

Alternatively, the third compound may contain any one third metal selected from the group consisting of cerium (Ce) and gadolinium (Gd), and the fourth compound may contain another fourth metal selected from the group consisting of lanthanum (La), strontium (Sr), hafnium (Hf), and zirconium (Zr).

The step of supplying the third purge gas may be performed simultaneously with stopping the supply of the second source gas. The third purge gas may use various purge gases known in the art, and the second source gas remaining in the vacuum deposition apparatus is purged by the supply of the third purge gas.

The step of supplying the second reaction gas may be performed simultaneously with stopping the supply of the third purge gas.

The second reaction gas may be formed of O₃, H₂O, or a mixture of O₃ and H₂O.

The second reaction gas may be formed of the same material as the first reaction gas, but is not limited thereto.

The step of supplying the fourth purge gas may be performed simultaneously with stopping the supply of the second reaction gas. The fourth purge gas may use various purge gases known in the art, and the second reaction gas remaining in the vacuum deposition apparatus is purged by the supply of the fourth purge gas.

According to another embodiment of this inventive concept, one cycle is completed by a combination of the first source gas supply step, the first purge gas supply step, the first reaction gas supply step, the second purge gas supply step, the second source gas supply step, the third purge gas supply step, the second reaction gas supply step, and the third purge gas supply step, and the dielectric film may be formed by repeating the cycle.

The dielectric film formed according to another embodiment of this inventive concept may include a first dielectric film formed by reacting the first source gas with the first reaction gas and a second dielectric film on the first dielectric film and formed by reacting the second source gas with the second reaction gas. The dielectric layer may have a structure in which the first dielectric layer and the second dielectric layer are repeatedly stacked.

The first dielectric film may be formed of an oxide of any one first metal contained in the first compound or an oxide of a composite metal including any one first metal contained in the first compound and another second metal contained in the second compound.

The second dielectric film may be formed of an oxide of any one third metal contained in the third compound or an oxide of a composite metal including any one third metal contained in the third compound and another fourth metal contained in the fourth compound.

FIG. 4 is a schematic cross-sectional view of a capacitor according to an embodiment of the present inventive concept.

As shown in FIG. 4, a capacitor in accordance with one embodiment of this inventive concept contains a first electrode 101, a dielectric film 200, and a second electrode 300.

Each of the first electrode 101 and the second electrode 300 may be formed of a conductive material such as a metal, a conductive metal oxide, a conductive metal nitride, or a conductive silicon compound. The first electrode 101 and the second electrode 300 may be formed of the same material or different materials.

The dielectric film 200 is provided between the first electrode 101 and the second electrode 300.

The dielectric film 200 may be formed by the method according to FIG. 1 or FIG. 2 described above. Therefore, the dielectric film 200 may be made of an oxide of any one first metal of lanthanum (La), cerium (Ce), strontium (Sr), gadolinium (Gd), hafnium (Hf), or zirconium (Zr).

Alternatively, the dielectric film 200 may be made of an oxide of a composite metal including any one first metal of lanthanum (La), cerium (Ce), strontium (Sr), gadolinium (Gd), hafnium (Hf), or zirconium (Zr) and another second metal of lanthanum (La), cerium (Ce), strontium (Sr), gadolinium (Gd), hafnium (Hf), or zirconium (Zr).

For example, the composite metal may contain any one first metal selected from the group consisting of lanthanum (La), cerium (Ce), strontium (Sr), and gadolinium (Gd), and another second metal selected from the group consisting of hafnium (Hf) and zirconium (Zr).

Alternatively, the composite metal may contain any one first metal selected from the group consisting of cerium (Ce) and gadolinium (Gd), and another second metal selected from the group consisting of lanthanum (La), strontium (Sr), hafnium (Hf), and zirconium (Zr).

FIG. 5 is a schematic cross-sectional view of a capacitor according to another embodiment of the present inventive concept.

As shown in FIG. 5, a capacitor in accordance with another embodiment of this inventive concept includes a first electrode 101, a dielectric film 200, and a second electrode 300.

The first electrode 101 and the second electrode 300 are the same as described above.

The dielectric film 200 is provided between the first electrode 101 and the second electrode 300, and can be formed by the method in accordance with FIG. 3.

The dielectric film 200 includes a first dielectric layer 210 and a second dielectric layer 220.

The first dielectric layer 210 may be formed of an oxide of any one first metal of lanthanum (La), cerium (Ce), strontium (Sr), gadolinium (Gd), hafnium (Hf), and zirconium (Zr). Alternatively, the first dielectric layer 210 may be made of an oxide of a composite metal including any one first metal of lanthanum (La), cerium (Ce), strontium (Sr), gadolinium (Gd), hafnium (Hf), or zirconium (Zr) and another second metal of lanthanum (La), cerium (Ce), strontium (Sr), gadolinium (Gd), hafnium (Hf), or zirconium (Zr).

The second dielectric layer 220 is provided on the first dielectric layer 210 and is formed of a material different from the first dielectric layer 210.

The second dielectric layer 220 may be formed of an oxide of any one third metal of lanthanum (La), cerium (Ce), strontium (Sr), gadolinium (Gd), hafnium (Hf), or zirconium (Zr). The third metal is different from the first metal. Alternatively, the third metal is different from the first metal and the second metal.

Alternatively, the second dielectric layer 220 may be formed of an oxide of a composite metal including any one third metal of lanthanum (La), cerium (Ce), strontium (Sr), gadolinium (Gd), hafnium (Hf), or zirconium (Zr), and another fourth metal of lanthanum (La), cerium (Ce), strontium (Sr), gadolinium (Gd), hafnium (Hf), or zirconium (Zr). The third metal is different from the first metal. Alternatively, the third metal is different from the first metal and the second metal. The fourth metal is different from the first metal and the third metal. Alternatively, the fourth metal is different from the first metal, the second metal, and the third metal.

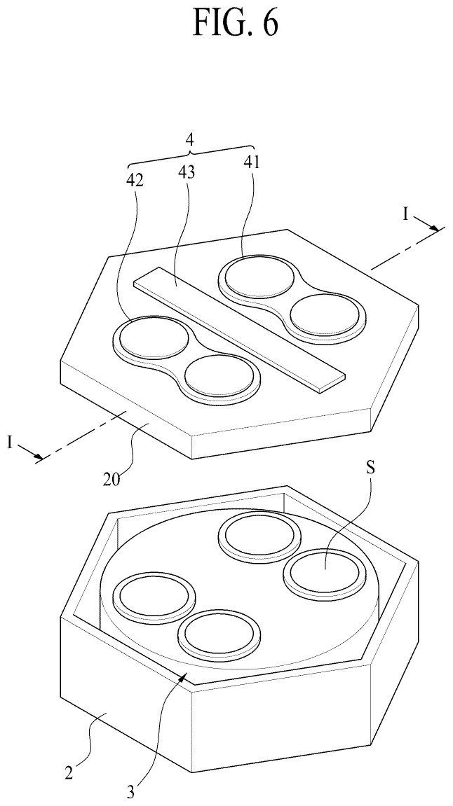

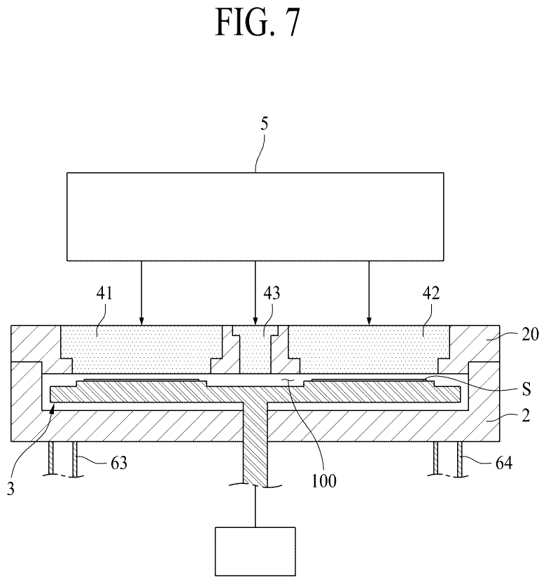

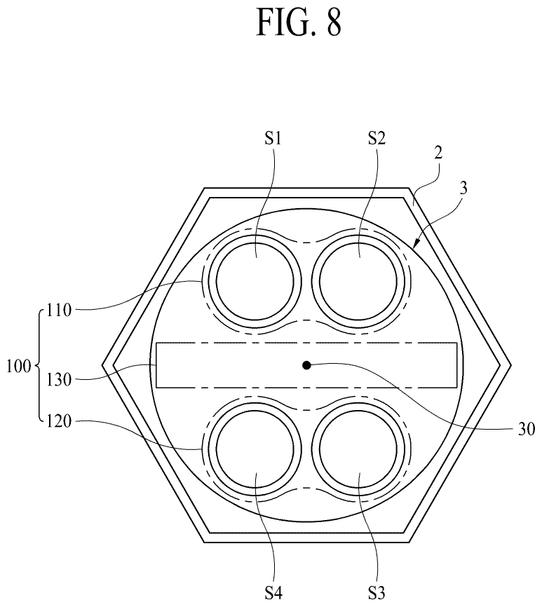

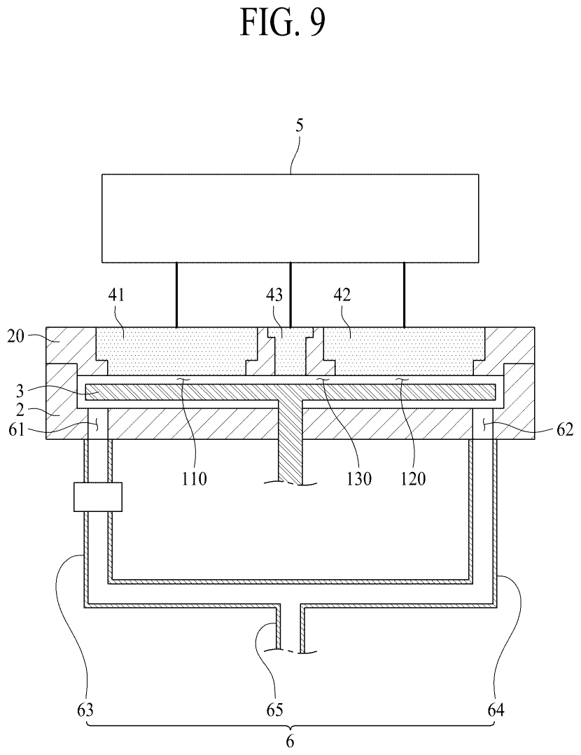

FIG. 6 is a schematic exploded perspective view of a vacuum deposition apparatus according to an embodiment of the present inventive concept. FIG. 7 is a schematic side cross-sectional view of a vacuum deposition apparatus according to an embodiment of the present inventive concept based on line I-I of FIG. 6. FIG. 8 is a schematic plan view of a support portion in a vacuum deposition apparatus according to an embodiment of the present inventive concept. FIG. 9 is a schematic side cross-sectional view of a vacuum deposition apparatus according to another embodiment of the present inventive concept based on line I-I of FIG. 6.

Referring to FIGS. 6 to 9, a vacuum deposition apparatus according to the present inventive concept performs a processing process on a substrate S, in detail, performs method of forming a dielectric film according to various embodiments described above. The substrate S may be a glass substrate, a silicon substrate, a metal substrate, or the like.

The vacuum deposition apparatus according to the present inventive concept may include a chamber 2, a supporting unit 3, a gas injection unit 4, a gas supply unit 5, and an exhaust unit 6.

The chamber 2 provides a processing space 100. In the processing space 100, deposition of the dielectric film may be performed on the substrate S. The processing space 100 may include a first processing region 110, a second processing region 120, and a third processing region 130 between the first processing region 110 and the second processing region 120, in the chamber 2. The supporting unit 3 and the gas injection unit 4 may be installed in the chamber 2.

The supporting unit 3 may be disposed in the chamber 2. The supporting unit 3 may support one substrate S, or may support a plurality of substrates S1 to S4. In a case where the processing space 100 includes the first processing region 110, the second processing region 120, and the third processing region 130, a portion of the supporting unit 3 may be disposed in the first processing region 110, another portion of the supporting unit 3 may be disposed in the second processing region 120, and another portion of the supporting unit 3 may be disposed in the third processing region 130. In a case where the plurality of substrates S1 to S4 are supported by the supporting unit 3, some of the plurality of substrates S1 to S4 may be disposed in the first processing region 110, and the other substrates may be disposed in the second processing region 120. In this case, a dielectric film deposition process may be simultaneously performed on each of a plurality of substrates S1, S2, S3, and S4.

The supporting unit 3 may rotate with respect to a supporting shaft 30 of the supporting unit 3 in the chamber 2. Based on a rotation of the supporting unit 3, the substrates S supported by the supporting unit 3 may respectively move to different processing regions in the chamber 2. When the supporting unit 3 rotates, some of the plurality of substrates S1 to S4 may move from the first processing region 110 to the second processing region 120 via the third processing region 130 and may again move from the second processing region 120 to the first processing region 110 via the third processing region 130. A rotation of the supporting unit 3 may be repeatedly stopped and performed, or may be continuously performed without stopping. Accordingly, the substrates S supported by the supporting unit 3 may respectively move to the different processing regions by repeatedly performing a stop operation and a movement operation, or may continuously move without stopping.

The gas injection unit 4 injects a gas toward the supporting unit 3. The gas injection unit 4 may be connected to the gas supply unit 5. Therefore, the gas injection unit 4 may inject a gas, supplied from the gas supply unit 5, toward the supporting unit 3. The gas injection unit 4 may be disposed to be opposite to the supporting unit 3. The processing space 100 may be disposed between the gas injection unit 4 and the supporting unit 3. The gas injection unit 4 may be coupled to a chamber lid 20. The chamber lid 20 is coupled to the chamber 2 to cover an upper portion of the chamber 2.

The gas injection unit 4 may include a first injection unit 41 and a second injection unit 42.

The first injection unit 41 injects a gas into the first processing region 110. The first processing region 110 may correspond to a portion of the processing space 100. The first injection unit 41 may be disposed upward apart from the supporting unit 3. In this case, the first processing region 110 may be a region between the first injection unit 41 and the supporting unit 3. The first injection unit 41 may inject a source gas and a purge gas into the first processing region 110.

Therefore, a processing process using the source gas may be performed on a substrate S disposed in the first processing region 110. In a case where the source gas reacts with a reaction gas to deposit a dielectric film, the processing process may be a process of adsorbing the source gas onto a surface of the substrate S. Also, the purge gas may purge the source gas, which is not adsorbed onto the substrate S, in the first processing region 110. In a case where some substrates S1 and S2 of the plurality of substrates S1 to S4 supported by the supporting unit 3 are disposed in the first processing region 110, the source gas and the purge gas injected from the first injection unit 41 may be sequentially injected on the substrates S1 and S2.

The source gas and the purge gas may include the first source gas and the first purge gas of FIG. 1. Alternatively, the source gas and the purge gas may include the first source gas, the first purge gas, the second source gas, and the second purge gas of FIG. 2 or 3. In this case, the first source gas, the first purge gas, the second source gas, and the second purge gas may be injected in order from the first injection unit 41.

The second injection unit 42 injects a second gas into the second processing region 120. The second processing region 120 may correspond to a portion of the processing space 100. The second injection unit 42 may be disposed upward apart from the supporting unit 3. In this case, the second processing region 120 may be a region between the second injection unit 42 and the supporting unit 3.

The second injection unit 42 may inject a reaction gas and a purge gas into the second processing region 120.

The reaction gas and the purge gas may include the first reaction gas and the second purge gas of FIG. 1. Alternatively, the reaction gas and the purge gas may include the first reaction gas and the third purge gas of FIG. 2. Alternatively, the reaction gas and the purge gas may include the first reaction gas and the second purge gas, the second reaction gas, and the fourth purge gas of FIG. 3. In this case, the first reaction gas, the second purge gas, the second reaction gas, and the fourth purge gas may be injected in order from the second injection unit 42.

Therefore, a processing process using the second gas may be performed on a substrate S disposed in the second processing region 120. In a case where the second gas reacts with the first gas to form a thin film, the processing process may be a process of reacting the first gas adsorbed onto the substrate S with the second gas to form a dielectric film on a surface of the substrate S. Also, the purge gas may additionally purge the first gas, remaining in the surface of the substrate S, in the second processing region 120, or may purge the second gas which does not react with the first gas. In a case where some substrates S1 and S2 of a plurality of substrates S1 to S4 supported by the supporting unit 3 are disposed in the first processing region 110, some other substrates S3 and S4 may be disposed in the second processing region 120.

The gas injection unit 4 may further include a third injection unit 43.

The third injection unit 43 injects a gas into the third processing region 130. The third processing region 130 may correspond to a portion of the processing space 100. The third processing region 130 may be a region between the first processing region 110 and the second processing region 120. The third injection unit 43 may be disposed upward apart from the supporting unit 3. The third injection unit 43 may be disposed between the first injection unit 41 and the second injection unit 42.

The third injection unit 43 may inject a division gas into the third processing region 130. The division gas may be an inert gas such as argon (Ar). As the third injection unit 43 injects the division gas into the third processing region 130, the first processing region 110 and the second processing region 120 may be spatially separate from each other so that a gas is not mixed therebetween. The third injection unit 43 may be connected to the gas supply unit 5. In a case where some substrates S1 and S2 of a plurality of substrates S1 to S4 supported by the supporting unit 3 are disposed in the first processing region 110 and some other substrates S3 and S4 may be disposed in the second processing region 120, the third injection unit 43 may inject the division gas into a space between the substrates S1 and S2 disposed in the first processing region 110 and the substrates S3 and S4 disposed in the second processing region 120.

The gas supply unit 5 supplies a gas to the gas injection unit 4. The gas supply unit 5 may supply the gas injection unit 4 with the first and second source gas, the first and second reaction gas, and the first to fourth purge gas. In a case where the gas injection unit 4 injects the division gas, the gas supply unit 5 may additionally supply the division gas to the gas injection unit 4. In this case, the gas supply unit 5 may intermittently or continuously supply the division gas to the third injection unit 43 while a processing process is being performed on the substrate S.

The exhaust unit 6 exhausts a gas from the processing space 100. The exhaust unit 6 may be coupled to the chamber 2 to communicate with an inner portion of the chamber 2.

The exhaust unit 6 may include a first exhaust port 61, a second exhaust port 62, a first exhaust member 63, a second exhaust member 64, and an integration member 65.

The first exhaust port 61 and the second exhaust port 62 may be formed as a plurality of exhaust ports in the chamber 2. The first exhaust port 61 may be formed in the chamber 2 so as to exhaust the first processing region 110. The second exhaust port 62 may be formed in the chamber 2 so as to exhaust the second processing region 120.

The first exhaust member 63 may be provided for exhausting the first processing region 110 through the first exhaust port 61. A gas injected into the first processing region 110 may be exhausted to the outside of the chamber 2 through the first exhaust port 61 and the first exhaust member 63. One side of the first exhaust member 63 may be coupled to the first exhaust port 61 formed in the chamber 2, and the other side thereof may be coupled to the integration member 65.

The second exhaust member 64 may be provided for exhausting the second processing region 120 through the second exhaust port 62. A gas injected into the second processing region 120 may be exhausted to the outside of the chamber 2 through the second exhaust port 62 and the second exhaust member 64. One side of the second exhaust member 64 may be coupled to the second exhaust port 62 formed in the chamber 2, and the other side thereof may be coupled to the integration member 65.

The integration member 65 is connected to each of the first exhaust member 63 and the second exhaust member 64. A gas exhausted through the first exhaust member 63 and a gas exhausted through the second exhaust member 64 may be combined in the integration member 65 and may be exhausted. Each of the integration member 65, the second exhaust member 64, and the first exhaust member 63 may be implemented with a hose, a pipe, or the like.

In a case where the source gas is injected into the first processing region 110 and the reaction gas is injected into the second processing region 120, an unreacted gas of the source gas may be exhausted from the chamber 2 through the first exhaust member 63, and an unreacted gas of the reaction gas may be exhausted from the chamber 2 through the second exhaust member 64.

Hereinabove, the embodiments of the present inventive concept have been described in more detail with reference to the accompanying drawings, but the present inventive concept is not limited to the embodiments and may be variously modified within a range which does not depart from the technical spirit of the present inventive concept. Therefore, it should be understood that the embodiments described above are exemplary from every aspect and are not restrictive. It should be construed that the scope of the present inventive concept is defined by the below-described claims instead of the detailed description, and the meanings and scope of the claims and all variations or modified forms inferred from their equivalent concepts are included in the scope of the present inventive concept.

1. A method of forming a dielectric film, the method comprising:
a step of supplying a first source gas;
a step of supplying a first purge gas;
a step of supplying a first reaction gas; and
a step of supplying a second purge gas,
wherein the step of supplying the first source gas comprises supplying a compound containing at least one metal selected from the group consisting of lanthanum (La), cerium (Ce), strontium (Sr), gadolinium (Gd), hafnium (Hf), and zirconium (Zr) into a vacuum deposition apparatus, and
wherein the step of supplying the first reaction gas comprises supplying a compound selected from the group consisting of O₃ and H₂O into the vacuum deposition apparatus.

2. The method of forming a dielectric film of claim 1, wherein the step of supplying the first source gas comprises supplying a first compound containing a first metal selected from the group consisting of lanthanum (La), cerium (Ce), strontium (Sr), gadolinium (Gd), hafnium (Hf), and zirconium (Zr), and a second compound different from the first compound and including a second metal selected from the group consisting of lanthanum (La), cerium (Ce), strontium (Sr), gadolinium (Gd), hafnium (Hf), and zirconium (Zr).

3. The method of forming a dielectric film of claim 2, wherein the first metal is selected from the group consisting of lanthanum (La), cerium (Ce), strontium (Sr), and gadolinium (Gd), and the second metal is selected from the group consisting of hafnium (Hf) and zirconium (Zr).

4. The method of forming a dielectric film of claim 1, further comprising:
a step of supplying a second source gas between the step of supplying the first purge gas and the step of supplying the first reaction gas; and
a step of supplying a third purge gas between the step of supplying the second source gas and the step of supplying the first reaction gas;
wherein the step of supplying the first source gas comprises supplying a first compound containing a first metal selected from the group consisting of lanthanum (La), cerium (Ce), strontium (Sr), gadolinium (Gd), hafnium (Hf), and zirconium (Zr) into a vacuum deposition apparatus,
wherein the step of supplying the second source gas comprises supplying a second compound containing a second metal different from the first metal and selected from the group consisting of lanthanum (La), cerium (Ce), strontium (Sr), gadolinium (Gd), hafnium (Hf), and zirconium (Zr) into the vacuum deposition apparatus, and
wherein the step of supplying the first reaction gas comprises supplying a compound selected from the group consisting of O3 and H2O into the vacuum deposition apparatus.

5. The method of forming a dielectric film of claim 4, wherein the first metal is selected from the group consisting of lanthanum (La), cerium (Ce), strontium (Sr), and gadolinium (Gd), and the second metal is selected from the group consisting of hafnium (Hf) and zirconium (Zr).

6. The method of forming a dielectric film of claim 1, further comprising:
a step of supplying a second source gas after the step of supplying the second purge gas;
a step of supplying a third purge gas;
a step of supplying a second reaction gas; and
a step of supplying a fourth purge gas,
wherein the step of supplying the first source gas comprises supplying a compound containing at least one metal selected from the group consisting of lanthanum (La), cerium (Ce), strontium (Sr), gadolinium (Gd), hafnium (Hf), and zirconium (Zr) into a vacuum deposition apparatus,
wherein the step of supplying the second source gas comprises supplying a compound containing at least one metal selected from the group consisting of lanthanum (La), cerium (Ce), strontium (Sr), gadolinium (Gd), hafnium (Hf), and zirconium (Zr) into the vacuum deposition apparatus,
wherein the second source gas is different from the first source gas, and wherein each of the step of supplying the first reaction gas and the step of supplying the second reaction gas comprises supplying a compound selected from the group consisting of O₃ and H₂O into the vacuum deposition apparatus.

7. The method of forming a dielectric film of claim 6, wherein the step of supplying the first source gas comprises supplying a first compound containing a first metal selected from the group consisting of lanthanum (La), cerium (Ce), strontium (Sr), gadolinium (Gd), hafnium (Hf), and zirconium (Zr) and a second compound containing a second metal selected from the group consisting of lanthanum (La), cerium (Ce), strontium (Sr), gadolinium (Gd), hafnium (Hf), and zirconium (Zr) into the vacuum deposition apparatus, the second compound being different from the first compound, and
wherein the step of supplying the second source gas comprises supplying a third compound containing a third metal selected from the group consisting of lanthanum (La), cerium (Ce), strontium (Sr), gadolinium (Gd), hafnium (Hf), and zirconium (Zr) and a fourth compound containing a fourth metal selected from the group consisting of lanthanum (La), cerium (Ce), strontium (Sr), gadolinium (Gd), hafnium (Hf), and zirconium (Zr) into the vacuum deposition apparatus, the fourth compound being different from the third compound.

8. (canceled)

9. A dielectric film comprising an oxide of a composite metal, wherein the composite metal includes a first metal selected from the group consisting of lanthanum (La), cerium (Ce), strontium (Sr), gadolinium (Gd), hafnium (Hf), and zirconium (Zr), and a second metal selected from the group consisting of lanthanum (La), cerium (Ce), strontium (Sr), gadolinium (Gd), hafnium (Hf), and zirconium (Zr), the second metal being different from the first metal.

10. The dielectric film of claim 9, wherein the first metal is selected from the group consisting of lanthanum (La), cerium (Ce), strontium (Sr), and gadolinium (Gd), and the second metal is selected from the group consisting of hafnium (Hf) and zirconium (Zr).

11. A dielectric film comprising:
a first dielectric film; and
a second dielectric film on the first dielectric film and formed of a different material from the first dielectric film,
wherein the first dielectric film comprises an oxide of a first metal, or an oxide of a composite metal comprising a first metal and a second metal, the first metal being different from the second metal,
wherein the second dielectric film comprises an oxide of a third metal, or an oxide of a composite metal comprising a third metal and a fourth metal, the third metal being different from the fourth metal, and
wherein each of the first metal, the second metal, the third metal and the fourth metal is selected from the group consisting of lanthanum (La), cerium (Ce), strontium (Sr), gadolinium (Gd), hafnium (Hf), and zirconium (Zr).

12. (canceled)
